(19) United States
(12) Patent Application Publication
(10) Pub. No.: US 2012/0167983 A1
(43) Pub. Date: Jul. 5, 2012

(54) COMPOSITE LIGHT CONVERTER FOR POLYCRYSTALLINE SILICON SOLAR CELL AND SILICON SOLAR CELL USING THE CONVERTER

(76) Inventors: Sung Mea Cho, Daejeon (KR); Jae Suk Sung, Daejeon (KR); Man Woong Park, Gyeongsan-si (KR); Ko Yeon Choo, Daejeon (KR); Suck Jin Son, Daejeon (KR); Tae Bum Lee, Gyeongsanbuk-do (KR); Soshchin Naum, Moscow (RU)

(21) Appl. No.: 13/377,897

(22) PCT Filed: Jul. 22, 2010
(86) PCT No.: PCT/KR10/04813

§ 371 Date: Dec. 13, 2011

(30) Foreign Application Priority Data
Jun. 29, 2010 (KR) 10-2010-0061638

(51) Int. Cl. H01L 31/0232; B82Y 99/00

(52) U.S. Cl. 136/257; 977/948

(57) ABSTRACT

A composite light converter for polycrystalline silicon solar cell and silicon solar cell using the converter includes a composite light converter disposed on the surface of a polycrystalline solar cell and connected by the electrode ribbon; upper and lower ethylene-vinyl acetate (EVA) sheets disposed such that the solar cell and the composite light converter are disposed between the EVA sheets; a low iron tempered glass disposed on the upper EVA sheet to transmit light; and a back sheet disposed under the lower EVA sheet and formed of a fluorine film or a PET film. Here, the composite light converter is a polymer binder containing light-emitting components, in which a polymer layer is formed on the surface of a polycrystalline silicon wafer comprising an electrode; the polymer layer is formed of two types of nano inorganic components that are active filling materials inside the converter.

### BACKGROUND OF THE INVENTION

The present invention relates to a composite light converter for a polycrystalline silicon solar cell and silicon solar cell using the converter, and more particularly, to a solar cell that is formed by stacking a composite light converter on a polycrystalline silicon solar cell, the composite light converter being based on a fluorescent material that facilitates increase of a wavelength band generating a photovoltaic effect among the absorption spectrum of sunlight.

The photoelectric apparatuses that can generate electricity from sunlight as alternative energy have been accepted as a representative technology for green power because it can get energy without discharging toxic gases and greenhouse gases to the air.

The lifespan of solar cells is known as over 50 years. The solar cell that had been first produced in 1957 was based on a monocrystalline silicon wafer, but has been developed into various generations of solar cells through continuous research and development.

As described above, the first generation solar cell was based on monocrystalline silicon, i.e. a mono-silicon material, and the second and third generation solar cells were variously developed based on thin films of various compounds such as tellurium and selenium. Generally, solar cells based on silicon may be divided into three types of a monocrystalline silicon wafer, a polycrystalline silicon wafer that is called multi- or poly-silicon, and a silicon thin film that is amorphously hydrogenated to a thickness of about 1 μm to about 2 μm.

Among the three types of solar cell devices, the monocrystalline silicon wafer and the polycrystalline silicon wafer make use of p-n transition of charge carrier pairs generated in silicon due to irradiation of active light. For this, the silicon wafers include phosphorus with a depth of about 10 μm to about 50 μm on the surface thereof. Since the phosphorus exists as electrical impurities on the surface of the silicon wafer, the phosphorus may be mostly formed in an n-layer, but may diffuse into a p-layer.

Particularly, a polycrystalline silicon wafer is similar to a monocrystalline silicon wafer in their arrangement, but both silicon wafers physically show a quantitative difference in mobility of electrons and holes in material.

Since monocrystalline silicon has almost no structural defects and impurities, its electron mobility is a relatively high. However, since polycrystalline silicon has various crystal sizes and amorphous crystal structures due to many crystal boundaries between crystal blocks independently grown, its electron mobility is lower than monocrystalline silicon because electron carriers are interrupted from moving at boundaries between crystal blocks and therefore polycrystalline silicon is cheaper than monocrystalline silicon.

Since the characteristics of mobility of the carriers influence the efficiency of a silicon photoelectric device, solar cells using monocrystalline silicon have a maximum of about 24% light conversion efficiency when a light collector is not used, and have about 28% or more light conversion efficiency when the light collector is used. However, the light conversion efficiency of solar cells using polycrystalline silicon is known as η=12-13% when a light collector is not used. Accordingly, research and development of solar cells to improve the light conversion efficiency of cheap polycrystalline silicon are being extensively made.

### SUMMARY OF THE INVENTION

The present invention provides a composite light converter for a polycrystalline silicon solar cell and a silicon solar cell using the same, which can reduce power generation cost using sun light by designing technology that can increase the power generation efficiency and durability of a solar cell using polycrystalline silicon having an advantage in terms of cost.

Hereinafter, the electrical and physical characteristics of a solar cell wafer will be described in detail.

First, the open-circuit voltage Voc and the short-circuit current density Jsc may be defined in Voc-Jsc coordinate regarding voltage V and current A in a device test. The fill factor FF specifically shows the overall sharing of charge carriers divided by p-n transition of a silicon wafer device.

Generally, the open-circuit voltage V0 of a solar cell using monocrystalline silicone may be about 7% to about 12% greater than that of a solar cell using polycrystalline silicon. However, the fill factor FF using polycrystalline silicon may be about 25% to about 30% smaller than that of a solar cell using monocrystalline silicon due to carrier loss. This results from a difference between sunlight spectrum and photosensitive spectrum of a silicon solar cell.

FIG. 2 is a view illustrating a sunlight spectrum at a northern latitude of about 37.5 degrees. FIG. 3 is a view illustrating a photocurrent of a polycrystalline silicon wafer varying with the spectral structure of light. The curve shown in FIG. 3 corresponds to the photosensitive spectrum of silicon.

As shown in FIG. 2, sunlight shows the maximum intensity at a wavelength λ of about 470 nm. The sunlight spectrum covers an infrared range in which the wavelength is greater than 1 μm, and an ultraviolet range in which the wavelength is smaller than 290 μm. Light of the ultraviolet range with 290 μm or less is fully absorbed by the atmosphere. When comparing the sunlight spectrum with the photosensitive spectrum curve of a silicon wafer shown in FIG. 3, the photosensitive spectrum of the silicon wafer shows the maximum photosensitivity at a wavelength of about 980 nm where its energy is about two times smaller than that of sunlight.

Sunlight reaching the earth has the highest energy at a wavelength of about 470 nm. However, a silicon solar cell uses the photosensitive wavelength band ranging from about 400 nm to 1,100 nm as shown in FIG. 3, while the maximum photosensitivity is generated at a wavelength of about 980 nm for the maximum electricity production. Thus, since the maximum wavelength band of sunlight is different from the maximum photosensitivity wavelength of a silicon solar cell, it is necessary to match them for the maximum electricity production.

Accordingly, it is necessary to make a polycrystalline silicon wafer to show the maximum photosensitivity at the above wavelength. Energy E of about 1.2 eV corresponds to energy of a forbidden region of silicon, and the wavelength λ of about 470 nm with the maximum sunlight intensity is associated with the quantum energy hν of about 2.8 eV. Accordingly, when comparing energy values of about 1.2 eV and 2.8 eV, a silicon wafer is heated while being accompanied by a loss of neutron thermalization in which its energy disappears by half or more in absorption of blue solar quantum.

Also, since quanta of sunlight having smaller energy than a wavelength corresponding to energy of the forbidden region of silicon are very slightly absorbed into a silicon wafer, most quanta may be heated while passing the silicon wafer. This leads to a loss on the surface of the wafer, which reduces Voc, Jsc, and the fill factor of carriers. Also, since a sunlight loss occurs due to optical reflection, various methods for reducing the loss are being extensively studied to increase the efficiency of a solar cell using silicon.

For example, the efficiency of a monocrystalline silicon device can be increased up to about 15% to about 20%, by analyzing spectral mismatch between sunlight and the optimal photosensitivity of a monocrystalline silicon wafer and using a light spectrum converter containing phosphor based thereon. However, when this method is applied to a cheap polycrystalline silicon device, polycrystalline silicon shows a significant loss due to carrier diffusion. Accordingly, there are limitations in that an efficiency increase effect does not occur like monocrystalline silicon, and the efficiency is further reduced due to wafer heating according to increase of thickness when the device is manufactured using polycrystalline silicon having a thickness of about 260 μm to about 280 μm.

The present invention provides a composite light converter for a polycrystalline silicon solar cell, which can increase the efficiency of a solar cell using relatively cheap polycrystalline silicon and can improve durability by uniformly increasing the action of the converter on a polycrystalline silicon wafer.

The present invention also provides a composite light converter for a polycrystalline silicon solar cell, which can reduce the unit production cost of electricity by a solar cell with the efficiency improvement of the polycrystalline silicon solar cell, by stacking the light converter on a polycrystalline wafer and light-converting light of non-photosensitivity wavelength, at which electricity is not generated in a solar cell, into light of photosensitivity wavelength to increase the electricity generation efficiency.

In accordance with an exemplary embodiment, a polycrystalline silicon solar cell module includes: a polycrystalline solar cell; a composite light converter disposed on the surface of the solar cell and connected by the electrode ribbon; upper and lower ethylene-vinyl acetate (EVA) sheets disposed such that the solar cell and the composite light converter are disposed between the EVA sheets; a low iron tempered glass disposed on the upper EVA sheet to transmit light; and a back sheet disposed under the lower EVA sheet and formed of a fluorine film or a PET film, wherein: the composite light converter is a polymer binder containing light-emitting components, in which a polymer layer is formed on the surface of a polycrystalline silicon wafer including an electrode; the polymer layer is formed of two types of nano inorganic components that are active filling materials inside the converter; one of nano inorganic components is formed of spherical light-emitting nano silicon, and the other is formed of nano particles of anti-stokes phosphor based on oxychalcogenide of rare-earth elements that are activated by ions such as Yb, Er, and Ho.

The polymer layer may further include carbon nanotube.

The spherical light-emitting nano silicon formed in the polymer layer of the composite light converter may have a size of about 10 nm to about 50 nm, and may absorb a short wavelength of sunlight and effectively emit light within a range of about 610 nm to about 800 nm.

The polymer layer formed in the composite light converter may be filled with a phosphor of about 50 nm to about 200 nm, and the phosphor may be excited by infrared sunlight in a wavelength range of about 950 nm to about 1,100 nm to emit light at a red range of a visible spectrum.

The polymer layer of the composite light converter 4 may have a thickness of about 50 μm to about 200 μm, and may be formed on a polycrystalline silicon wafer having a thickness of about 120 μm to about 300 μm.

The content of the inorganic components in the polymer layer of the composite light converter may be allowed not to exceed about 10 wt. % The optimal content of the inorganic components may range from about 0.2 wt. % to about 2 wt. %. The ratio of nano silicon to nano phosphor, which are the two types of inorganic components in the polymer layer, may range from 1:5 to 5:1. The content of carbon nanotube may range from about 0.01 wt. % to about 0.3 wt. % when the carbon nanotube is contained.

The polymer binder of the composite light converter, which is thermosetting polymer, may be formed of polymer of an epoxy group such as —C—O—C—, or a silicon group such as —Si—O—C—C—Si—, and a mean molecular weight of the epoxy polymer may range from about 15,000 to about 18,000, and a mean molecular weight of the silicon polymer may range from about 20,000 to about 25,000.

In the composite light converter, the front surface of a polycrystalline silicon solar cell having sizes of 20 mm×20 mm to 156 mm×156 mm may be covered by optically-transparent silicate glass.

The polycrystalline silicon solar cell module including the composite light converter may include 36 to 72 solar cells connected in series or in parallel to each other.

A polycrystalline silicon solar cell using a composite light converter according to an embodiment of the present invention can increase electrical parameters such as open-circuit voltage, short-circuit current, and fill factor of a solar cell by contacting the surface of a polycrystalline silicon wafer.

Thus, since the electricity generation efficiency of a solar cell can increase from about 10%-13% to about 17%-18% as shown in FIGS. 7 and 8, and the electricity generation efficiency can uniformly increase by applying converter technology to a polycrystalline wafer, unit electricity generation cost of a solar cell can be significantly reduced.

### BRIEF DESCRIPTION OF DRAWINGS

Exemplary embodiments can be understood in more detail from the following description taken in conjunction with the accompanying drawings, in which:

FIG. 1 is a cross-sectional view illustrating a composite light converter for a polycrystalline solar cell according to an embodiment of the present invention;

FIG. 2 is a view illustrating a sunlight spectrum at a northern latitude of 37.5 degrees;

FIG. 3 is a view illustrating a photocurrent of a polycrystalline silicon wafer varying with the spectral structure of light, the curve of which corresponds to the photosensitive spectrum of silicon.

FIG. 4 is a SEM view of nano-silicon used in a test;

FIG. 5 is a view illustrating the spectrum of light reflected by a cell coated with silicon-based polymer in a spectral range from about 300 nm to about 1,100 nm;

FIG. 6 is a view illustrating the spectrum of light reflected by a cell coated with epoxy-based polymer in a spectral range from about 300 nm to about 1,100 nm;

FIG. 7 is a view illustrating a result of analyzing the performance of a converter in which spherical nano-silicon and oxychalcogenide phosphor are mixed with polymer, which is obtained by measuring parameters before and after a composite light converter is formed in a polycrystalline silicon wafer; and

FIG. 8 is a view illustrating a result of analyzing the performance of a converter in which spherical nano-silicon, oxychalcogenide phosphor and carbon nanotube are mixed with polymer, which is obtained by measuring parameters before and after a composite light converter is formed in a polycrystalline silicon wafer.

### DETAILED DESCRIPTION OF THE INVENTION

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

Hereinafter, a composite light converter for a polycrystalline silicon solar cell and a solar cell using the converter according to an embodiment of the present invention will be described in detail with reference to the accompanying drawings.

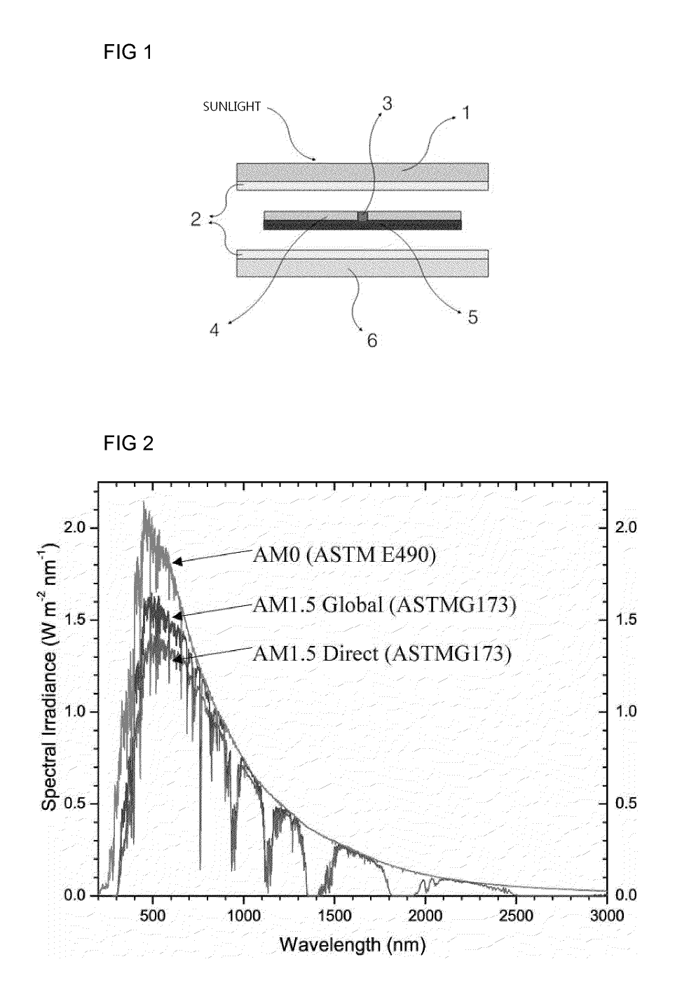

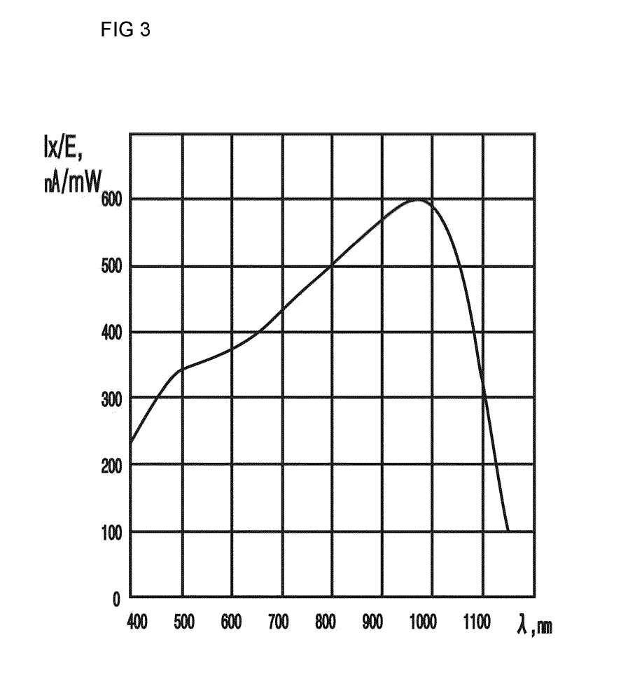

As shown in FIG. 1, a polycrystalline silicon solar cell module may include a polycrystalline solar cell 5, a composite light converter 4, an electrode ribbon 3, upper and lower ethylene-vinyl acetate (EVA) sheets 2, a low iron tempered glass 1, and a back sheet 6. The composite light converter 4 may be disposed on the surface of the solar cell 5, and may be connected by the electrode ribbon 3. The upper and lower EVA sheets 2 may be disposed such that the solar cell 5 and the composite light converter 4 are disposed between the EVA sheets 2. The low iron tempered glass 1 may be disposed on the upper EVA sheet 2 to transmit light. The back sheet 6 may be disposed under the lower EVA sheet 2, and may be formed of fluorine film or PET film.

The composite light converter 4 included in the solar cell 5 may be a polymer binder containing light-emitting components, in which a polymer layer may be formed on the surface of a polycrystalline silicon wafer including an electrode. The polymer layer may be formed of two types of nano inorganic components that are active filling materials inside the converter. One of nano inorganic components may be formed of spherical light-emitting nano silicon, and the other may be formed of nano particles of anti-stokes phosphor based on oxychalcogenide of rare-earth elements that are activated by ions such as Yb, Er, and Ho.

Also, carbon nanotube may be added to the polymer layer of the composite light converter 4 to be used as a charge transporting layer or an electrode.

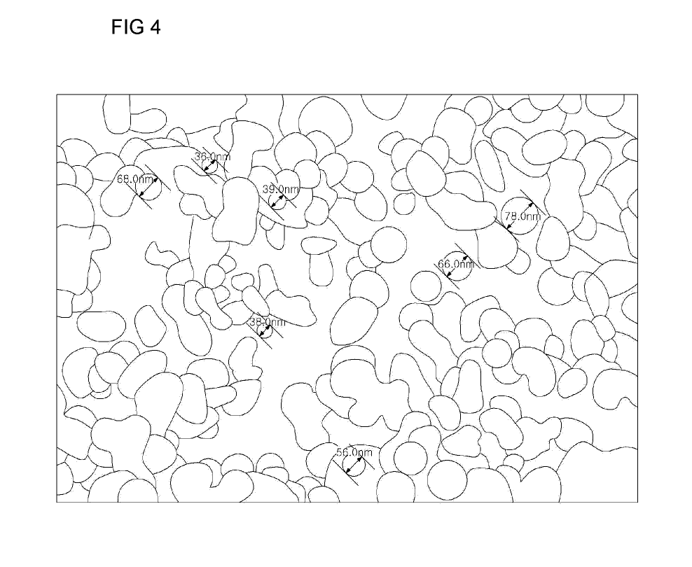

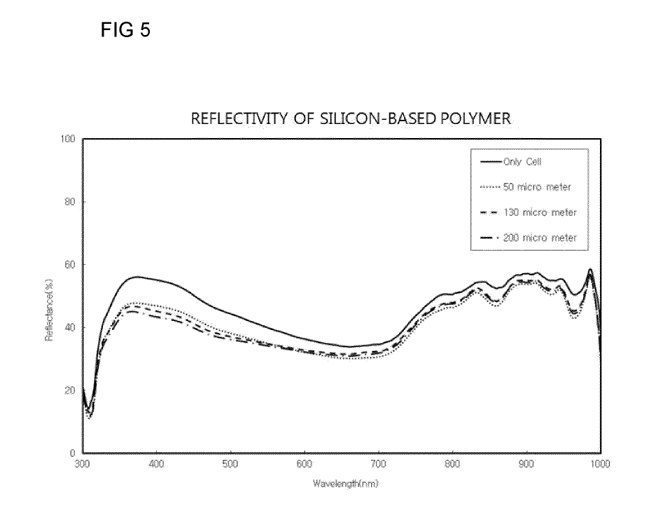

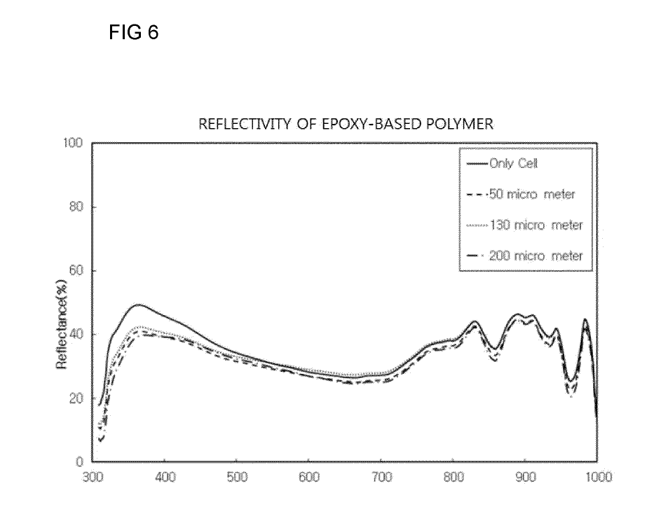

The polymer layer constituting the composite light converter 4 may be filled with silicon of nano size. As shown in FIG. 4, light-emitting nano silicon filled in the polymer layer may include spherical particles having sizes of about 10 nm to about 50 nm, and may absorb a short wavelength of sunlight and effectively emit within a range of about 610 nm to about 800 nm.

The polymer layer formed in the composite light converter 4 may be filled with phosphor of nano size. The phosphor may include oxychalcogenide of rare-earth elements that are activated by ions such as Yb, Er, and Ho, and may have a size of about 50 nm to about 200 nm. The phosphor may be excited by infrared sunlight in a wavelength range of about 950 nm to about 1,100 nm to emit light at a red range of a visible spectrum.

Also, the polymer layer formed in the composite light converter 4 may have a thickness of about 50 μm to about 200 μm, and may be formed on a polycrystalline silicon wafer having a thickness of about 120 μm to about 300 μm.

When the thickness of the polymer layer formed in the composite light converter is smaller than 50 μm, the reflection effect of polycrystalline silicon is not reduced. Also, when the thickness of the polymer layer is greater than about 20° μm, the efficiency does not increase. Accordingly, considering expense, it is not desirable to use a material for thickening the polymer layer. Also, when the thickness of the polymer layer is great, the hardening term of a thick film of the composite light convert 4 may be also lengthened, leading to increase of cost for a final product. Accordingly, the optimal thickness of the polymer layer for increasing the efficiency of a solar cell may range from about 5° μm to about 20° μm.

When the polymer layer is applied to the composite light converter 4 with a thickness of about 5° μm to about 200 μm, the maximum content of inorganic components in the polymer layer may be allowed not to exceed 10 wt. % The optimal content of the inorganic components may range from about 0.2 wt. % to about 2 wt. %.

Also, the ratio of inorganic component of nano silicon to inorganic component of nano phosphor in the polymer layer, ranges from 1:5 to 5:1.

In the composite light converter 4, suspension in which inorganic components are formed in a polymer binder may be coated on the front surface of a polycrystalline solar cell by dipping, printing, and spraying methods, and then may be thermally hardened for about 0.5 to 5 hours at a higher temperature than 100° C. to improve the hardness and the durability of a coated portion.

The polymer binder of the composite light converter 4, which is thermosetting polymer, may be formed of a plurality of epoxy or silicon resin (molecular weight M ranges from 15,000 to 25,000) having carbon unit and having an epoxy group such as —C—O—C—, or a silicon group such as —Si—O—C—C—Si—. The mean molecular weight of the epoxy polymer may range from about 15,000 to about 18,000, and the silicon polymer may use epoxy polymer whose mean molecular weight ranges from about 20,000 to about 25,000.

Also, in the composite light converter 4, the front surface of a polycrystalline silicon solar cell having sizes of 20 mm×20 mm to 156 mm×156 mm may be covered by optically-transparent silicate glass. The solar cell module including the composite light converter 4 as a component may include 36 to 72 solar cells connected in series or in parallel to each other.

A method for manufacturing such a composite light converter for a solar cell may include coating a suspension, in which inorganic components are diffused in a polymer binder, on the front surface of a polycrystalline solar cell by one of dipping, printing, and spraying methods, and then performing polymerization for about 0.5 to 5 hours at a higher temperature than 100° C.

When carbon nanotube is mixed with inorganic components of the polymer layer of the composite light converter to be utilized as a charge transporting layer or an electrode, the content of the inorganic components may be allowed not to exceed about 10 wt. %. The optimal content may range from about 0.2 wt. % to about 2.0 wt. %. The weight % of carbon nanotube may range from about 0.01 wt. % to about 0.3 wt. %.

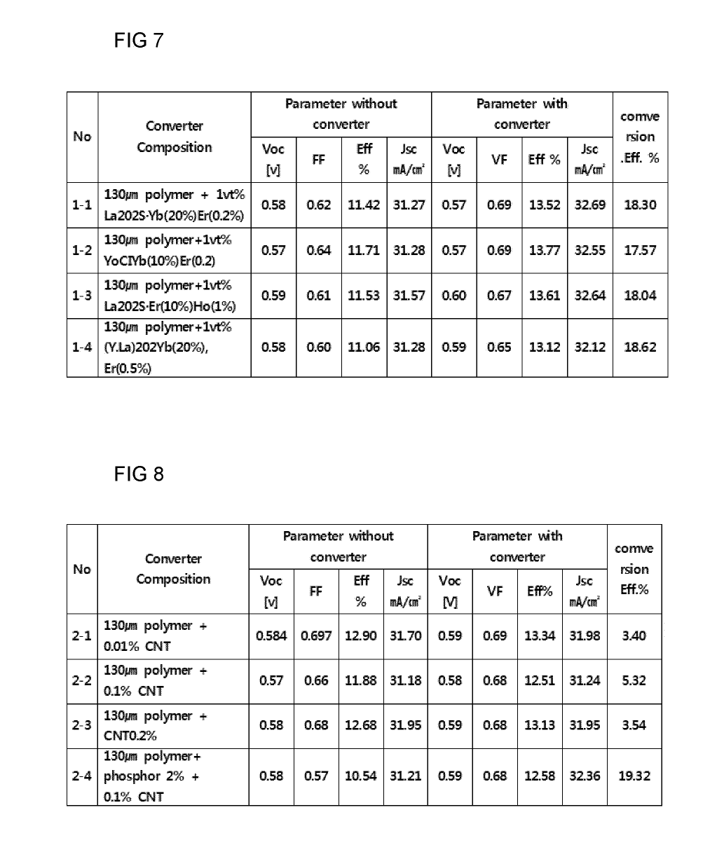

In a solar cell having such a structure, as shown in the test result of FIG. 7, the composite light converter 4 including the polymer layer filled with two types of inorganic components may contact the surface of a polycrystalline silicon wafer to increase electrical parameters such as open-circuit voltage, short-circuit current, and fill factor and thus increase the total efficiency of the solar cell from about 17% to about 18%.

When carbon nanotube is mixed into the composite light converter, as shown in the test result of FIG. 8, the conversion efficiency can be significantly increased. The light conversion efficiency may increase about 3.4% to about 5.3% when comparing a converter in which carbon nanotube of about 0.01% to about 0.2% is mixed with polycrystalline silicon of about 130 μm with an otherwise converter. However, when comparing a converter in which carbon nanotube of about 0.1% and inorganic phosphor of about 2% are mixed with an otherwise converter, it can be understood that the light conversion efficiency increases about 19.3%.

Although a composite light converter for a polycrystalline silicon solar cell and a silicon solar using the converter have been described with reference to the specific embodiments, they are not limited thereto. Therefore, it will be readily understood by those skilled in the art that various modifications and changes can be made thereto without departing from the spirit and scope of the present invention defined by the appended claims.

1. A composite light converter for polycrystalline silicon solar cell and silicon solar cell using the converter, comprising:
a polycrystalline silicon solar cell;
a composite light converter disposed on the surface of the solar cell and connected by the electrode ribbon;
upper and lower ethylene-vinyl acetate (EVA) sheets disposed such that the solar cell and the composite light converter are disposed between the EVA sheets;
a low iron tempered glass disposed on the upper EVA sheet to transmit light; and
a back sheet disposed under the lower EVA sheet and formed of a fluorine film or a PET film,
wherein the composite light converter is a polymer binder containing light-emitting components, in which a polymer layer is formed on the surface of a polycrystalline silicon wafer comprising an electrode;
the polymer layer is formed of two types of nano inorganic components that are active filling materials inside the converter;
one of nano inorganic components is formed of spherical light-emitting nano silicon, and the other is formed of nano particles of anti-stokes phosphor based on oxychalcogenide of rare-earth elements that are activated by ions such as Yb, Er, and Ho.

2. The composite light converter for polycrystalline silicon solar cell and silicon solar cell using the converter of claim 1, wherein the polymer layer further comprises carbon nanotube.

3. The composite light converter for polycrystalline silicon solar cell and silicon solar cell using the converter of claim 1, wherein the spherical light-emitting nano silicon formed in the polymer layer of the composite light converter has a size of about 10 nm to about 50 nm, and absorbs a short wavelength of sunlight and effectively emits light within a range of about 610 nm to about 800 nm.

4. The composite light converter for polycrystalline silicon solar cell and silicon solar cell using the converter of claim 3, wherein the polymer layer formed in the composite light converter is filled with a phosphor of about 50 nm to about 200 nm, and the phosphor is excited by infrared sunlight in a wavelength range of about 950 nm to about 1,100 nm to emit light at a red range of a visible spectrum.

5. The composite light converter for polycrystalline silicon solar cell and silicon solar cell using the converter of claim 4, wherein the polymer layer of the composite light converter has a thickness of about 50 μm to about 200 μm, and is formed on a polycrystalline silicon wafer having a thickness of about 120 μm to about 300 μm.

6. The composite light converter for polycrystalline silicon solar cell and silicon solar cell using the converter of claim 5, wherein:
the content of the inorganic components in the polymer layer of the composite light converter is allowed not to exceed about 10 wt. %;
the optimal content of the inorganic components ranges from about 0.2 wt. % to about 2 wt. %;
the ratio of inorganic component of nano silicon to inorganic component of nano phosphor in the polymer layer, ranges from 1:5 to 5:1; and
the content of carbon nanotube ranges from about 0.01 wt. % to about 0.3 wt. % when the carbon nanotube is contained.

7. The composite light converter for polycrystalline silicon solar cell and silicon solar cell using the converter of claim 6, wherein the polymer binder of the composite light converter, which is thermosetting polymer, is formed of polymer of an epoxy group such as —C—O—C—, or a silicon group such as —Si—O—C—C—Si—, and a mean molecular weight of the epoxy polymer ranges from about 15,000 to about 18,000, and a mean molecular weight of the silicon polymer ranges from about 20,000 to about 25,000.

8. The composite light converter for polycrystalline silicon solar cell and silicon solar cell using the converter of claim 7, wherein in the composite light converter 4, the front surface of a polycrystalline silicon solar cell having sizes of 20 mm×20 mm to 156 mm×156 mm is covered by optically-transparent silicate glass.

9. The composite light converter for polycrystalline silicon solar cell and silicon solar cell using the converter of claim 8, wherein the polycrystalline silicon solar cell module comprising the composite light converter comprises 36 to 72 solar cells connected in series or in parallel to each other.
